(19) United States
(12) Patent Application Publication
(10) Pub. No.: US 2015/0061153 A1
(43) Pub. Date: Mar. 5, 2015

(54) SEMICONDUCTOR DEVICE AND METHOD FOR MANUFACTURING THE SAME

(71) Applicant: Kabushiki Kaisha Toshiba, Minato-ku (JP)

(72) Inventors: Yoshiaki HIMENO, Mie-ken (JP); Yuki SOH, Mie-ken (JP); Hajime KANEKO, Mie-ken (JP)

(73) Assignee: Kabushiki Kaisha Toshiba, Minato-ku (JP)

(21) Appl. No.: 14/203,729

(22) Filed: Mar. 11, 2014

Related U.S. Application Data
(60) Provisional application No. 61/873,159, filed on Sep. 3, 2013.

(51) Int. Cl. H01L 23/48; H01L 21/768

(52) U.S. Cl. CPC H01L 23/481; H01L 21/76802; H01L 21/76877
USPC 257/774; 438/666

(57) ABSTRACT

According to one embodiment, a semiconductor device includes a semiconductor layer including a first region and a second region, a first insulating layer provided above the semiconductor layer, an extending first contact electrode, having a sidewall surrounded with the first insulating layer, and electrically connected to a first element provided in the first region, an extending second contact electrode, having a sidewall surrounded with the first insulating layer, and electrically connected to a second element provided in the second region, an extending first interconnection layer connected to an upper end of the first contact electrode, and having a sidewall surrounded with the first insulating layer, and an extending second interconnection layer connected to an upper end of the second contact electrode, having a sidewall surrounded with the first insulating layer, and having a line width wider than a line width of the first interconnection layer.

### CROSS-REFERENCE TO RELATED APPLICATIONS

This application is based upon and claims the benefit of priority from U.S. Provisional Patent Application 61/873,159, filed on Sep. 3, 2013; the entire contents of which are incorporated herein by reference.

### FIELD

Embodiments described herein relate generally to a semiconductor device and a method for manufacturing the same.

### BACKGROUND

In a nonvolatile semiconductor memory device in which a plurality of NAND memory strings are arranged, miniaturization has been increasingly advanced. With this miniaturization, contacts and interconnections connected to each of the plurality of memory strings also come close to each other.

In this situation, if an insulating layer having a relatively high permittivity is provided around the contact plug or interconnection, delay of interconnection signal speed is more likely to occur due to the influence of parasitic capacitance.

### BRIEF DESCRIPTION OF THE DRAWINGS

FIG. 1 is a schematic plan view showing the pattern layout of a memory cell section of a nonvolatile semiconductor memory device according to a first embodiment;

FIG. 2A is a schematic sectional view showing the select gate electrode, the control gate electrode, and the upper interconnection of the memory cell section according to the first embodiment, and FIG. 2B is a schematic sectional view showing the gate electrode and the upper interconnection of the peripheral section according to the first embodiment;

FIG. 3A to FIG. 5B are schematic sectional views showing the process for manufacturing the contact electrode and the interconnection layer of the nonvolatile semiconductor memory device according to the first embodiment;

FIG. 6A to FIG. 7C are schematic sectional views showing a process for manufacturing the contact electrode and the interconnection layer of a nonvolatile semiconductor memory device according to a reference example; and

FIG. 8A to FIG. 8D are schematic sectional views showing a process for manufacturing the contact electrode of a nonvolatile semiconductor memory device according to the second embodiment.

### DETAILED DESCRIPTION

According to one embodiment, a semiconductor device includes a semiconductor layer including a first region and a second region placed outside the first region, a first insulating layer provided above the semiconductor layer, a first contact electrode extending in a direction from the semiconductor layer toward the first insulating layer, having a sidewall surrounded with the first insulating layer, and electrically connected to a first element provided in the first region, a second contact electrode extending in the direction from the semiconductor layer toward the first insulating layer, having a sidewall surrounded with the first insulating layer, and electrically connected to a second element provided in the second region, a first interconnection layer connected to an upper end of the first contact electrode, extending in a direction crossing the extending direction of the first contact electrode, and having a sidewall surrounded with the first insulating layer, and a second interconnection layer connected to an upper end of the second contact electrode, extending in a direction crossing the extending direction of the second contact electrode, having a sidewall surrounded with the first insulating layer, and having a line width wider than a line width of the first interconnection layer.

Various embodiments will be described hereinafter with reference to the accompanying drawings. In the following description, like members are labeled with like reference numerals. The description of the members once described is omitted appropriately.

### First Embodiment

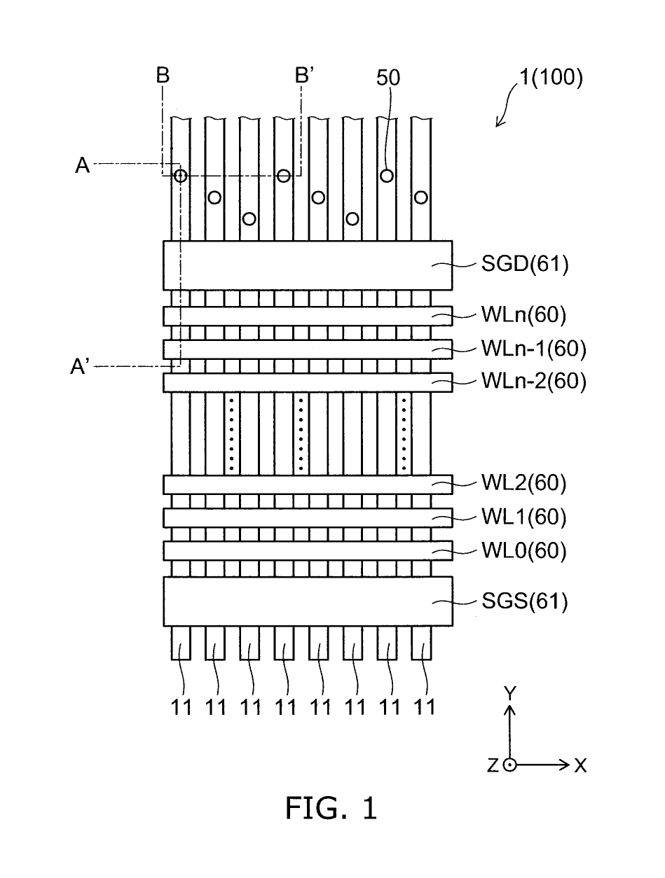

FIG. 1 is a schematic plan view showing the pattern layout of a memory cell section of a nonvolatile semiconductor memory device according to a first embodiment.

The nonvolatile semiconductor memory device 1 according to the first embodiment is what is called a NAND nonvolatile semiconductor memory device. The nonvolatile semiconductor memory device 1 includes a memory cell section (first region) and a peripheral section (second region) placed outside the memory cell section.

The memory cell section of the nonvolatile semiconductor memory device 1 is shown in FIG. 1.

In the memory cell section 100, a plurality of semiconductor regions 11 (element regions) are arranged in the X-direction. Element isolation regions are each provided between the plurality of semiconductor regions 11. A line-shaped control gate electrode 60 and a line-shaped select gate electrode 61 are provided in the X-direction crossing the Y-direction in which the semiconductor regions 11 extend. The select gate electrodes 61 include a drain-side select gate electrode SGD and a source-side select gate electrode SGS. A plurality of control gate electrodes 60 (control gate electrodes WL0-WLn) are sandwiched between the select gate electrode SGD and the select gate electrode SGS.

The memory cell section 100 includes memory cells at the crossing positions of the plurality of semiconductor regions 11 and the plurality of control gate electrodes 60. The semiconductor region 11 sandwiched between the select gate electrode SGD and the select gate electrode SGS is provided with a plurality of memory cells. The memory cell section 100 includes a memory string in which the select gate electrode SGD, a plurality of memory cells, and the select gate electrode SGS are connected in series in the Y-direction.

The memory cell section 100 is surrounded with e.g. a circuit for driving and controlling the memory cell section 100. For instance, the peripheral section 200 described later is provided with transistors, resistors, capacitors, interconnections, contact plugs and the like constituting the circuit.

The portions shown in FIG. 1 are illustrative only. The memory cell section 100 includes portions other than the portions shown in FIG. 1.

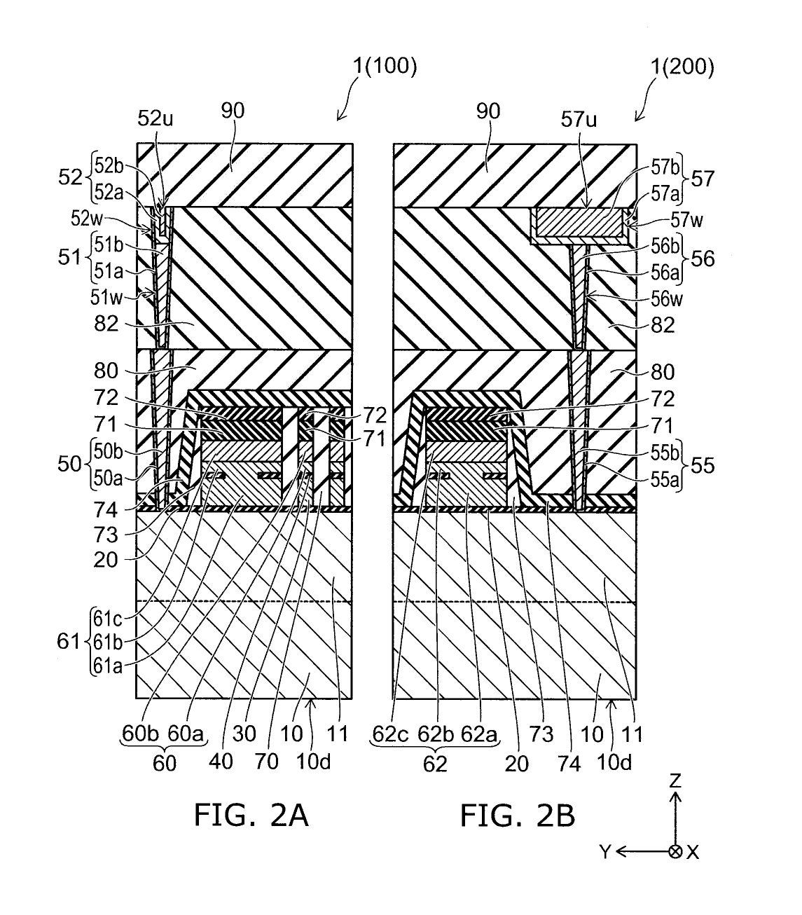

FIG. 2A is a schematic sectional view showing the select gate electrode, the control gate electrode, and the upper interconnection of the memory cell section according to the first embodiment. FIG. 2B is a schematic sectional view showing the gate electrode and the upper interconnection of the peripheral section according to the first embodiment. Here, FIG. 2A shows a cross section at the position taken along line A-A′ of FIG. 1.

The memory cell section 100 of the nonvolatile semiconductor memory device 1 shown in FIG. 2A includes a semiconductor layer 10, a semiconductor region 11, a control gate electrode 60, a select gate electrodes 61, a gate insulating film 20, a charge storage layer 30, and a gate insulating film 40. In the nonvolatile semiconductor memory device 1, the semiconductor region 11, the gate insulating film 20, the charge storage layer 30, and the gate insulating film 40 are provided at the crossing position of the semiconductor region 11 and the control gate electrode 60. In the memory cell section 100, the cell including the gate insulating film 20, the charge storage layer 30, the gate insulating film 40, and the control gate electrode 60 is referred to as e.g. memory cell.

The semiconductor layer 10 is e.g. a semiconductor substrate singulated from a semiconductor wafer. The semiconductor region 11 provided on the semiconductor layer 10 is an active region populated with transistors of the nonvolatile semiconductor memory device 1. Here, a diffusion region (source/drain region) is provided (not shown) in the semiconductor region 11 on both sides of the charge storage layer 30.

The gate insulating film 20 is provided between the charge storage layer 30 and the semiconductor region 11. The gate insulating film 20 functions as a tunnel insulating film for tunneling charge (e.g., electrons) between the semiconductor region 11 and the charge storage layer 30.

The charge storage layer 30 is provided at the crossing position of the semiconductor region 11 and the control gate electrode 60. The charge storage layer 30 covers the gate insulating film 20. The charge storage layer 30 can accumulate the charge tunneled from the semiconductor region 11 via the gate insulating film 20. The charge storage layer 30 may be referred to as floating gate layer.

The gate insulating film 40 is provided between the charge storage layer 30 and the control gate electrode 60. The gate insulating film 40 covers the charge storage layer 30. The side surface of the charge storage layer 30 is covered with an interlayer insulating film 70. That is, the upper surface and the side surface of the charge storage layer 30 are covered with insulator so that the charge accumulated in the charge storage layer 30 does not leak to the control gate electrode 60. The gate insulating film 40 may be referred to as charge block layer.

The control gate electrode 60 covers the charge storage layer 30 via the gate insulating film 40. The control gate electrode 60 includes a polysilicon-containing layer 60a and a metal-containing layer 60b provided above the polysilicon-containing layer 60a. The control gate electrode 60 functions as a gate electrode for controlling a transistor.

The select gate electrode 61 includes e.g. a polysilicon-containing layer 61a, a polysilicon-containing layer 61b, and a metal-containing layer 61c. The gate insulating film 20 is provided between the polysilicon-containing layer 61a and the semiconductor region 11. A diffusion region (source/drain region) is provided (not shown) in the semiconductor region 11 on both sides of the polysilicon-containing layer 61a. The select gate electrode 61, the gate insulating film 20, and the semiconductor region 11 described above constitute a select gate transistor (first element). One memory string is selected from among the plurality of memory strings by the select gate transistor.

Insulating layers 71, 72 are provided on the control gate electrode 60. Insulating layers 71, 72 are provided on the select gate electrode 61. A sidewall film 73 is provided on the sidewall of the select gate electrode 61. An insulating layer 74 is provided on the interlayer insulating film 70, on the insulating layer 72, on the sidewall film 73, and on the gate insulating film 20.

An insulating layer 80 is provided on the insulating layer 74. A contact electrode 50 (third contact electrode) is provided in the insulating layer 80. The contact electrode 50 includes e.g. a barrier layer 50a and a conductive layer 50b. The contact electrode 50 extends in the direction (Z-direction) from the semiconductor layer 10 toward the insulating layer 80. The lower end of the contact electrode 50 pierces the insulating layer 74 and is connected to the semiconductor region 11. The contact electrode 50 is electrically connected to the diffusion region of the select gate transistor.

An insulating layer 82 is provided on the insulating layer 80. A contact electrode 51 (first contact electrode) is provided in the insulating layer 82. The contact electrode 51 includes e.g. a barrier layer 51a and a conductive layer 51b. The contact electrode 51 extends in the direction (Z-direction) from the semiconductor layer 10 toward the insulating layer 82. The sidewall 51w of the contact electrode 51 is surrounded with the insulating layer 82. The contact electrode 51 is connected to the contact electrode 50. The contact electrode 51 is electrically connected to the select gate transistor of the memory cell section 100.

Furthermore, an interconnection layer 52 is provided in the insulating layer 82. The interconnection layer 52 is used as a bit line of the nonvolatile semiconductor memory device. The interconnection layer 52 includes e.g. a seed layer 52a and a conductive layer 52b. The interconnection layer 52 is connected to the upper end of the contact electrode 51. The interconnection layer 52 extends in a direction (e.g., X-direction) crossing the extending direction of the contact electrode 51. The sidewall 52w of the interconnection layer 52 is surrounded with the insulating layer 82. An insulating layer 90 is provided on the insulating layer 82.

The peripheral section 200 (peripheral circuit region) of the nonvolatile semiconductor memory device 1 shown in FIG. 2B includes a semiconductor layer 10, a semiconductor region 11, a gate electrodes 62, and a gate insulating film 20.

The semiconductor region 11 is an active region populated with transistors of the nonvolatile semiconductor memory device 1. The gate electrode 62 includes e.g. a polysilicon-containing layer 62a, a polysilicon-containing layer 62b, and a metal-containing layer 62c. The gate insulating film 20 is provided between the polysilicon-containing layer 62a and the semiconductor region 11. A diffusion region (source/drain region) is provided (not shown) in the semiconductor region 11 on both sides of the polysilicon-containing layer 62a. The gate electrode 62, the gate insulating film 20, and the semiconductor region 11 described above provide a transistor (second element) in the peripheral section 200.

Here, the second element provided in the peripheral section is not limited to the transistor. For instance, the element may be a resistor or capacitor. In the embodiment, a transistor is illustrated in FIG. 2B as an example of the second element.

Furthermore, insulating layers 71, 72 are provided on the gate electrode 62. A sidewall film 73 is provided on the sidewall of the gate electrode 62. An insulating layer 74 is provided on the insulating layer 72, on the sidewall film 73, and on the gate insulating film 20.

An insulating layer 80 is provided on the insulating layer 74. A contact electrode 55 is provided in the insulating layer 80. The contact electrode 55 includes e.g. a barrier layer 55a and a conductive layer 55b. The contact electrode 55 extends in the direction (Z-direction) from the semiconductor layer 10 toward the insulating layer 80. The lower end of the contact electrode 55 pierces the insulating layer 74 and is connected to the semiconductor region 11. The contact electrode 55 is electrically connected to the diffusion region of the transistor.

An insulating layer 82 is provided on the insulating layer 80. A contact electrode 56 (second contact electrode) is provided in the insulating layer 82. The contact electrode 56 includes a barrier layer 56a and a conductive layer 56b. The contact electrode 56 extends in the direction (Z-direction) from the semiconductor layer 10 toward the insulating layer 82. The sidewall 56w of the contact electrode 56 is surrounded with the insulating layer 82. The contact electrode 56 is connected to the contact electrode 55. The contact electrode 56 is electrically connected to the transistor of the peripheral section 200.

Furthermore, an interconnection layer 57 is provided in the insulating layer 82. The interconnection layer 57 includes a seed layer 57a and a conductive layer 57b. The interconnection layer 57 is connected to the upper end of the contact electrode 56. The interconnection layer 57 extends in a direction (e.g., X-direction) crossing the extending direction of the contact electrode 56. The line width of the interconnection layer 57 is wider than the line width of the interconnection layer 52. Here, the line width of the interconnection layer refers to the width of the interconnection layer cut perpendicular to the extending direction of the interconnection layer. The sidewall 57w of the interconnection layer 57 is surrounded with the insulating layer 82. The insulating layer 90 is provided on the insulating layer 82.

Furthermore, in the nonvolatile semiconductor memory device 1, the distance from the lower surface 10d of the semiconductor layer 10 to the upper end 52u of the interconnection layer 52 is equal to the distance from the lower surface 10d of the semiconductor layer 10 to the upper end 57u of the interconnection layer 57.

The material of the semiconductor layer 10 (or the semiconductor region 11) is e.g. a p-type (first conductivity type) semiconductor crystal. This semiconductor can be e.g. silicon (Si).

The material of the gate insulating film 20 is e.g. silicon oxide (SiOₓ), silicon nitride (SiₓN_{y}) or the like. The gate insulating film 20 may be e.g. a monolayer of silicon oxide film or silicon nitride film, or may be a stacked film of either silicon oxide film or silicon nitride film.

The material of the charge storage layer 30 may be e.g. a semiconductor material such as Si and Si-based compound, a material different therefrom (e.g., metal or insulating film), or a stacked film thereof. The material of the charge storage layer 30 is e.g. a semiconductor containing n-type (second conductivity type) impurity, a metal, a metal compound or the like. This material can be e.g. amorphous silicon (a-Si), polysilicon (poly-Si), silicon germanium (SiGe), silicon nitride (SiₓN_{y}), hafnium oxide (HfOₓ) or the like.

The gate insulating film 40 may be e.g. a monolayer of silicon oxide film or silicon nitride film, or may be a stacked film of either silicon oxide film or silicon nitride film. For instance, the gate insulating film 40 may be what is called an ONO film (silicon oxide film/silicon nitride film/silicon oxide film). Alternatively, the gate insulating film 40 may be a metal oxide film or metal nitride film.

The material of the barrier layer 50a, 51a, 55a, 56a is e.g. titanium (Ti), titanium nitride (TiNₓ) or the like. The material of the conductive layer 50b, 51b, 55b, 56b is e.g. tungsten (W) or the like. The material of the conductive layer 52b, 57b is e.g. copper (Cu) or the like.

The material of the polysilicon-containing layer 60a, 61a, 61b, 62a, 62b is e.g. a semiconductor containing an impurity element. This semiconductor can be polysilicon. The material of the metal-containing layer 60b, 61c, 62c is e.g. a metal such as tungsten, or metal silicide.

In the embodiment, the material of the portion referred to as insulating film, insulating layer, or sidewall film is e.g. silicon oxide (SiOₓ) or silicon nitride (SiₓN_{y}).

In the embodiment, the first conductivity type is p-type, and the second conductivity type is n-type. However, the first conductivity type may be n-type, and the second conductivity type may be p-type. The p-type impurity element can be e.g. boron (B). The n-type impurity element can be e.g. phosphorus (P) or arsenic (As).

A process for manufacturing the contact electrode and the interconnection layer in the nonvolatile semiconductor memory device 1 is now described.

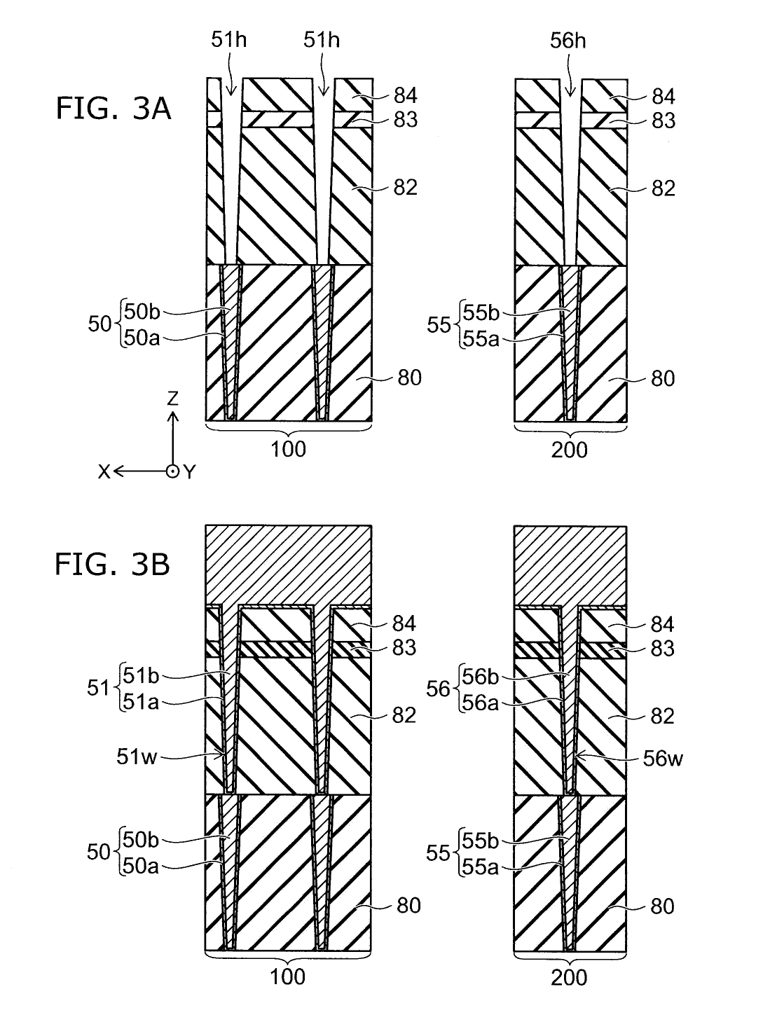

FIGS. 3A to 5B are schematic sectional views showing the process for manufacturing the contact electrode and the interconnection layer of the nonvolatile semiconductor memory device according to the first embodiment.

FIGS. 3A to 5B each show the memory cell section 100 and the peripheral section 200, but do not show the semiconductor region 11. Here, in the memory cell section 100, each figure shows a cross section corresponding to the position of line B-B′ of FIG. 1.

First, before the state shown in FIG. 3A, a semiconductor layer 10 is prepared. The semiconductor layer 10 is provided with select gate transistors and the like in the memory cell section 100, and further provided with transistors and the like in the peripheral section 200 (see FIGS. 2A and 2B).

Next, the memory cell section 100 is subjected to the processing described below.

For instance, as shown in FIG. 3A, an insulating layer 82 (first insulating layer) is formed on the insulating layer 80 and on the contact electrode 50. That is, an insulating layer 82 is formed above the semiconductor layer 10.

Then, an insulating layer 83 (third insulating layer) different in composition from the insulating layer 82 is formed on the insulating layer 82. For instance, in the case where the insulating layer 80 is a silicon oxide layer, the insulating layer 83 is a silicon nitride layer (SiₓN_{y} layer). Alternatively, the insulating layer 83 may be a silicon carbonitride layer (SiCₓN_{y} layer). This insulating layer 83 functions as a stopper film (described later).

Then, an insulating layer 84 (fourth insulating layer) different in composition from the insulating layer 83 is formed on the insulating layer 83. For instance, the insulating layer 84 is a silicon oxide layer.

Then, a contact hole 51h is formed in the direction (Z-direction) from the insulating layer 84 toward the semiconductor layer 10 by photolithography and RIE (reactive ion etching). The contact hole 51h pierces the insulating layer 84, the insulating layer 83, and the insulating layer 82. The contact hole 51h opens the upper end of the contact electrode 50.

On the other hand, the peripheral section 200 is subjected to the processing described below.

For instance, as shown in FIG. 3A, the insulating layer 82 is formed on the insulating layer 80 and on the contact electrode 55. Then, the insulating layer 83 is formed on the insulating layer 82. Then, the insulating layer 84 is formed on the insulating layer 83.

Then, a contact hole 56h is formed in the Z-direction by photolithography and RIE. The contact hole 56h pierces the insulating layer 84, the insulating layer 83, and the insulating layer 82. The contact hole 56h opens the upper end of the contact electrode 55.

Here, in the memory cell section 100 and the peripheral section 200, the formation of the insulating layer 82, the insulating layer 83, and the insulating layer 84 can be simultaneously advanced. Furthermore, the formation of the contact hole 51h and the contact hole 56h can be simultaneously advanced.

The insulating layer 82, 83, 84 is formed by e.g. plasma CVD. The film thickness of the insulating layer 82 is e.g. 95 nm. The film thickness of the insulating layer 83 is e.g. 10 nm. The film thickness of the insulating layer 84 is e.g. 60 nm.

After forming the contact hole 51h, 56h, choline treatment at 70° C. for 5 minutes may be performed to remove natural oxide film at each upper end of the contact electrode 50, 55.

Next, the memory cell section 100 is subjected to the processing described below.

For instance, as shown in FIG. 3B, a barrier layer 51a is formed in the contact hole 51h and on the insulating layer 84. Then, a conductive layer 51b is formed via the barrier layer 51a in the contact hole 51h and on the insulating layer 84.

Thus, a contact electrode 51 (first contact electrode) extending in the Z-direction is formed. The sidewall 51w of the contact electrode 51 is surrounded with the insulating layer 82, the insulating layer 83, and the insulating layer 84. The contact electrode 51 is electrically connected to the aforementioned select transistor.

On the other hand, the peripheral section 200 is subjected to the processing described below.

For instance, as shown in FIG. 3B, a barrier layer 56a is formed in the contact hole 56h and on the insulating layer 84. Then, a conductive layer 56b is formed via the barrier layer 56a in the contact hole 56h and on the insulating layer 84.

Thus, a contact electrode 56 (second contact electrode) extending in the Z-direction is formed. The sidewall 56w of the contact electrode 56 is surrounded with the insulating layer 82, the insulating layer 83, and the insulating layer 84. The contact electrode 56 is electrically connected to the aforementioned transistor.

Here, in the memory cell section 100 and the peripheral section 200, the formation of the barrier layers 51a, 56a can be simultaneously advanced by sputtering film formation. The film thickness of the barrier layer 51a, 56a is e.g. 6 nm. Furthermore, in the memory cell section 100 and the peripheral section 200, the formation of the conductive layers 51b, 56b can be simultaneously advanced by sputtering film formation.

From the next figure onward, illustration of the structure below the insulating layer 82 is omitted.

Next, the memory cell section 100 is subjected to the processing described below.

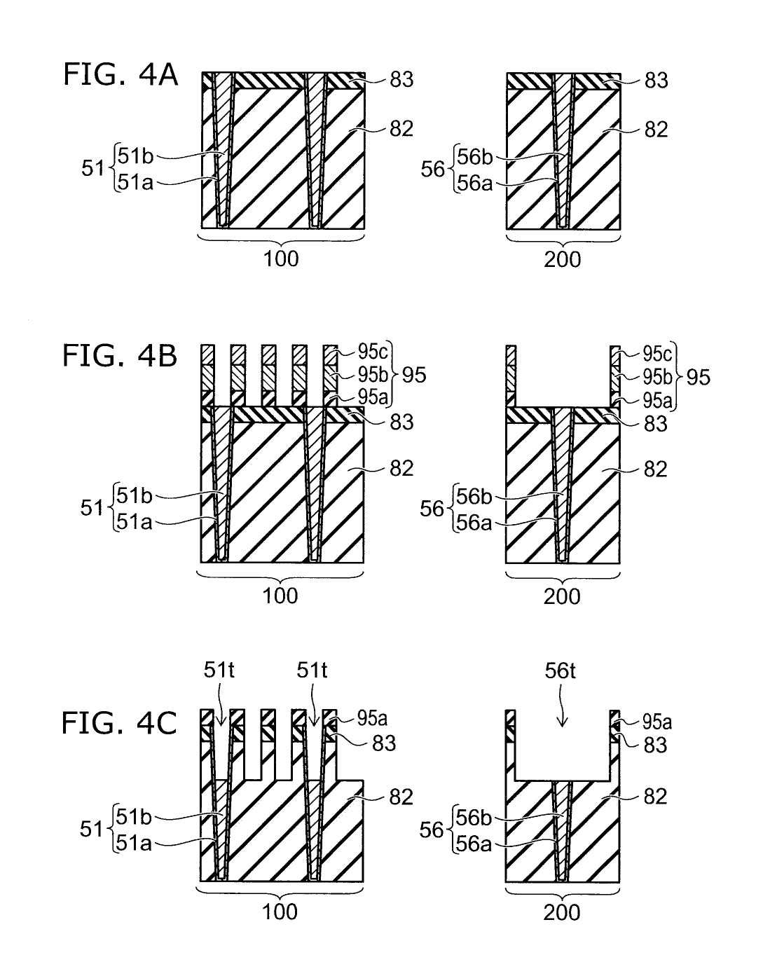

For instance, as shown in FIG. 4A, the insulating layer 84 and the contact electrode 51 above the insulating layer 83 are removed by CMP (chemical mechanical polishing).

On the other hand, the peripheral section 200 is subjected to the processing described below.

For instance, as shown in FIG. 4A, the insulating layer 84 and the contact electrode 56 above the insulating layer 83 are removed by CMP.

Here, the insulating layer 83 functions as a stopper film in CMP processing. Furthermore, in the memory cell section 100 and the peripheral section 200, the CMP processing can be simultaneously advanced. The contact electrodes 51, 56 and the insulating layer 83 are made flush with each other by this CMP processing. That is, the heights of the contact electrodes 51, 56 and the insulating layer 83 are made equal to each other.

Next, the memory cell section 100 is subjected to the processing described below.

For instance, as shown in FIG. 4B, a mask layer 95 opening the contact electrode 51 is formed on the insulating layer 83. The mask layer 95 includes a silicon oxide layer 95a, a polysilicon layer 95b provided on the silicon oxide layer 95a, and an amorphous silicon layer 95c provided on the polysilicon layer 95b.

On the other hand, the peripheral section 200 is subjected to the processing described below.

For instance, as shown in FIG. 4B, a mask layer 95 opening the contact electrode 56 and part of the insulating layer 83 in contact with the contact electrode 56 is formed. That is, the opening of the mask layer 95 in the peripheral section 200 is larger than the opening of the mask layer 95 in the memory cell section 100.

Here, in the memory cell section 100 and the peripheral section 200, the formation of the mask layer 95 can be simultaneously advanced.

Next, the memory cell section 100 is subjected to the processing described below.

For instance, as shown in FIG. 4C, etching (RIE) is performed on the contact electrode 51 opened through the mask layer 95 to form a trench 51t (first trench) with the bottom being the upper end of the contact electrode 51. Here, the upper end of the contact electrode 51 is located below the insulating layer 83. Subsequently, the polysilicon layer 95b and the amorphous silicon layer 95c are removed. At this time, the barrier layer 51a may be left as shown, or may be removed by RIE.

On the other hand, the peripheral section 200 is subjected to the processing described below.

For instance, as shown in FIG. 4C, etching (RIE) is performed on the contact electrode 56 and part of the insulating layer 83 in contact with the contact electrode 56 opened through the mask layer 95. This forms a trench 56t (second trench) with the bottom being the upper end of the contact electrode 56 and the insulating film 82 continuous with the upper end of the contact electrode 56. Subsequently, the polysilicon layer 95b and the amorphous silicon layer 95c are removed.

Here, in the memory cell section 100 and the peripheral section 200, the formation of the trenches 51t, 56t can be simultaneously advanced. Furthermore, each of the trenches 51t, 56t can be extended in a direction crossing the Z-direction.

In etching the contact electrode 56 and the insulating layer 83 opened through the mask layer 95, the contact electrode 56 and the insulating layer 83 can be simultaneously etched using a halogen-containing gas (e.g., Cl, HBr). Furthermore, the trench 56t is formed under a condition selected so that the insulating layer 83 and the contact electrode 56 have the same processing selection ratio.

After forming the trench 51t, 56t, choline treatment at 70° C. for 5 minutes may be performed to remove natural oxide film at each upper end of the contact electrode 51, 56.

Next, the memory cell section 100 is subjected to the processing described below.

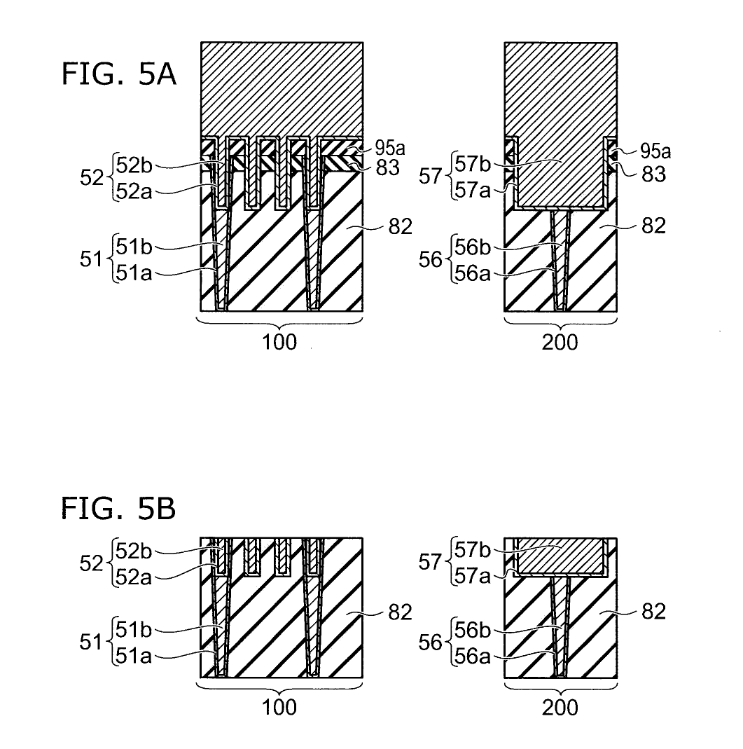

For instance, as shown in FIG. 5A, a seed layer 52a is formed above the insulating layer 83 and in the trench 51t. Then, a conductive layer 52b is formed via the seed layer 52a above the insulating layer 83 and in the trench 51t.

On the other hand, the peripheral section 200 is subjected to the processing described below.

For instance, as shown in FIG. 5A, a seed layer 57a is formed above the insulating layer 83 and in the trench 56t. Then, a conductive layer 57b is formed via the seed layer 57a above the insulating layer 83 and in the trench 56t.

Here, in the memory cell section 100 and the peripheral section 200, the formation of the seed layers 52a, 57a can be simultaneously advanced. Each of the seed layers 52a, 57a includes a titanium film (film thickness 8 nm) formed by sputtering film formation, and a copper film formed on the titanium film (film thickness 15 nm). Furthermore, in the memory cell section 100 and the peripheral section 200, the formation of the conductive layers 52b, 57b can be simultaneously advanced by plating technique. After forming the conductive layers 52b, 57b, the conductive layers 52b, 57b may be heated in a nitrogen-based atmosphere containing hydrogen at 150° C. for 30 minutes. This heating treatment decreases defects in the conductive layers 52b, 57b.

Next, the memory cell section 100 is subjected to the processing described below.

For instance, as shown in FIG. 5B, the seed layer 52a, the conductive layer 52b, and the insulating layer 83 above the junction of the insulating layer 82 and the insulating layer 83 are removed to form an interconnection layer 52 connected to the upper end of the contact electrode 51.

On the other hand, the peripheral section 200 is subjected to the processing described below.

For instance, as shown in FIG. 5B, the seed layer 57a, the conductive layer 57b, and the insulating layer 83 above the junction of the insulating layer 82 and the insulating layer 83 are removed to form an interconnection layer 57 connected to the upper end of the contact electrode 56.

Here, in the memory cell section 100 and the peripheral section 200, the removal of the seed layers 52a, 57a, the conductive layers 52b, 57b, and the insulating layer 83 can be simultaneously advanced. Subsequently, the interconnection layers 52, 57 are covered with an insulating layer 90. The insulating layer 90 is e.g. a silicon nitride layer. The film thickness of the insulating layer 90 is e.g. 60 nm.

Here, the removal of the seed layers 52a, 57a, the conductive layers 52b, 57b, and the insulating layer 83 is performed by methods described below.

For instance, as a first method, the seed layers 52a, 57a, the conductive layers 52b, 57b, and the insulating layer 83 are all removed by CMP.

Alternatively, as a second method, the layers above the insulating layer 83 are removed by CMP. Subsequently, the insulating layer 83 is removed by RIE. Then, the surface of the interconnection layer 52 and the surface of the interconnection layer 57 are polished by CMP until the interconnection layer 52 and the interconnection layer 57 reach a desired height.

Alternatively, as a third method, the layers above the insulating layer 83 are removed by CMP. Subsequently, the insulating layer 83 is removed by wet etching. Then, the surface of the interconnection layer 52 and the surface of the interconnection layer 57 are polished by CMP until the interconnection layer 52 and the interconnection layer 57 reach a desired height.

By such processes, the heights of the interconnection layers 52, 57 do not depend on the pattern width, but are made equal to each other.

### Reference Example

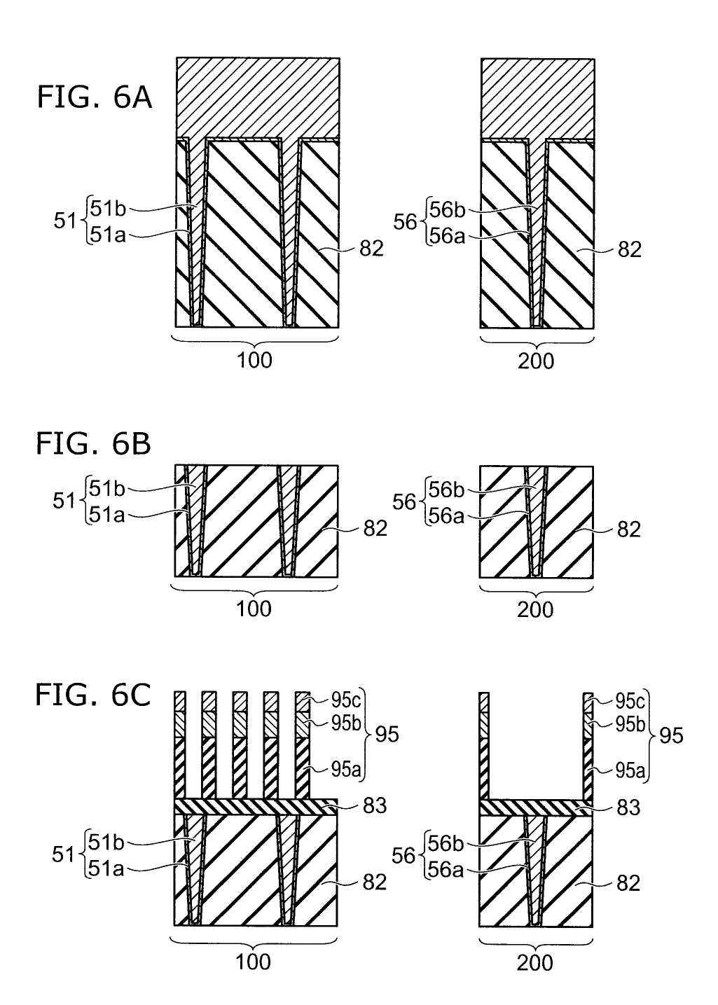

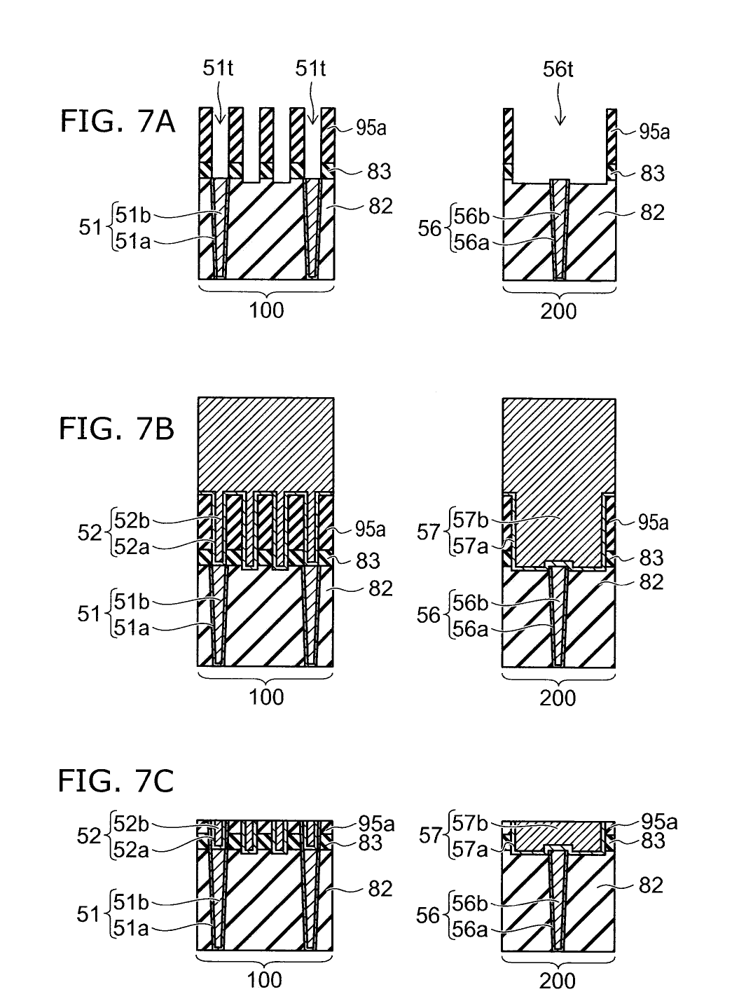

FIGS. 6A to 7C are schematic sectional views showing a process for manufacturing the contact electrode and the interconnection layer of a nonvolatile semiconductor memory device according to a reference example.

In the memory cell section 100, FIGS. 6A to 7C each show a cross section corresponding to the position of line B-B′ of FIG. 1.

In the reference example, the insulating layers 83, 84 are not provided on the insulating layer 82, but a contact electrode is previously formed in the insulating layer 82.

For instance, in the memory cell section 100, as shown in FIG. 6A, a barrier layer 51a is formed in the contact hole 51h and on the insulating layer 84. Then, a conductive layer 51b is formed via the barrier layer 51a in the contact hole 51h and on the insulating layer 84. Thus, a contact electrode 51 extending in the Z-direction is formed.

On the other hand, the peripheral section 200 is subjected to the processing described below.

For instance, as shown in FIG. 6A, a barrier layer 56a is formed in the contact hole 56h and on the insulating layer 84. Then, a conductive layer 56b is formed via the barrier layer 56a in the contact hole 56h and on the insulating layer 84. Thus, a contact electrode 56 extending in the Z-direction is formed.

Next, the memory cell section 100 is subjected to the processing described below.

For instance, as shown in FIG. 6B, the contact electrode 51 above the insulating layer 82 is removed by CMP.

On the other hand, the peripheral section 200 is subjected to the processing described below.

For instance, as shown in FIG. 6B, the contact electrode 56 above the insulating layer 82 is removed by CMP.

Next, the memory cell section 100 is subjected to the processing described below.

For instance, as shown in FIG. 6C, an insulating layer 83 is formed on the insulating layer 82. Then, a mask layer 95 opening the upper side of the contact electrode 51 is formed on the insulating layer 83.

On the other hand, the peripheral section 200 is subjected to the processing described below.

For instance, as shown in FIG. 6C, an insulating layer 83 is formed on the insulating layer 82. A mask layer 95 opening the upper side of the contact electrode 56 and the upper side of part of the insulating layer 83 in contact with the contact electrode 56 is formed. Here, the opening of the mask layer 95 in the peripheral section 200 is larger than the opening of the mask layer 95 in the memory cell section 100.

Here, the mask layer 95 is formed by photolithography and RIE. At this time, the insulating layer 83 functions as a stopper film for suppressing the loading effect during etching. The depths of the opening of the mask layer 95 in the memory cell section 100 and the peripheral section 200 are made equal to each other by the presence of this stopper film.

Next, the memory cell section 100 is subjected to the processing described below.

For instance, as shown in FIG. 7A, etching is performed on the insulating layer 83 opened through the mask layer 95 to form a trench 51t with the bottom being the upper end of the contact electrode 51. Subsequently, the polysilicon layer 95b and the amorphous silicon layer 95c are removed.

On the other hand, the peripheral section 200 is subjected to the processing described below.

For instance, as shown in FIG. 7A, etching (RIE) is performed on the insulating layer 83 opened through the mask layer 95. This forms a trench 56t with the bottom being the upper end of the contact electrode 56 and the insulating film 82 continuous with the upper end of the contact electrode 56. Subsequently, the polysilicon layer 95b and the amorphous silicon layer 95c are removed.

Next, the memory cell section 100 is subjected to the processing described below.

For instance, as shown in FIG. 7B, a seed layer 52a is formed above the silicon oxide layer 95a and in the trench 51t. Then, a conductive layer 52b is formed via the seed layer 52a above the silicon oxide layer 95a and in the trench 51t.

On the other hand, the peripheral section 200 is subjected to the processing described below.

For instance, as shown in FIG. 7B, a seed layer 57a is formed above the silicon oxide layer 95a and in the trench 56t. Then, a conductive layer 57b is formed via the seed layer 57a above the silicon oxide layer 95a and in the trench 56t.

Next, the memory cell section 100 is subjected to the processing described below.

For instance, as shown in FIG. 7C, the seed layer 52a and the conductive layer 52b are removed so as to leave the silicon oxide layer 95a and the insulating layer 83. This is because the removal of the silicon oxide layer 95a and the insulating layer 83 results in the removal of the seed layer 52a and the conductive layer 52b. Thus, an interconnection layer 52 connected to the upper end of the contact electrode 51 is formed.

On the other hand, the peripheral section 200 is subjected to the processing described below.

For instance, as shown in FIG. 7C, the seed layer 57a and the conductive layer 57b are removed so as to leave the silicon oxide layer 95a and the insulating layer 83. Thus, an interconnection layer 57 connected to the upper end of the contact electrode 56 is formed.

In the manufacturing process shown in the reference example, in the stage shown in FIG. 6C, an insulating layer 83 is formed to suppress the loading effect during etching. Then, this insulating layer 83 is left until the stage shown in FIG. 7C. The insulating layer 83 includes silicon nitride having higher relative permittivity than silicon oxide. Furthermore, the insulating layer 83 is in contact with the interconnection layer 52, 57.

Thus, in the structure shown in FIG. 7C, parasitic capacitance near the interconnection layer 52, 57 is increased. Increased parasitic capacitance near the interconnection layer 52, 57 causes delay of interconnection signal speed. The delay of interconnection signal speed becomes more significant as the pitch between interconnection layers becomes smaller.

In contrast, in the first embodiment, the insulating layer 83 is not in contact with the interconnection layer 52, 57. In the first embodiment, the insulating layer 83 is not used as a layer for suppressing the loading effect during etching, but used as a stopper film in CMP processing shown in FIG. 4A. Then, the insulating layer 83 is entirely removed in the stage shown in FIG. 5B.

Thus, in the first embodiment, parasitic capacitance near the interconnection layer 52, 57 is lower than that in the reference example. This suppresses delay of interconnection signal speed. Furthermore, in the first embodiment, because there is no insulating layer 83, there is no problem of the delay of interconnection signal speed even if the pitch between interconnection layers becomes smaller.

### Second Embodiment

FIG. 3A illustrates the case where there is no misalignment between the bottom of the contact hole 51h and the upper end of the contact electrode 50. However, with the miniaturization of the contact hole 51h and the contact electrode 50, the misalignment therebetween is more likely to occur. Here, the misalignment between the contact hole 51h and the contact electrode 50 refers to the state in which the center line of the contact hole 51h and the center line of the contact electrode 50 are displaced from each other.

According to the second embodiment, even if the aforementioned misalignment occurs, the contact electrode 51 formed in the contact hole 51h can be reliably made continuous with the contact electrode 50.

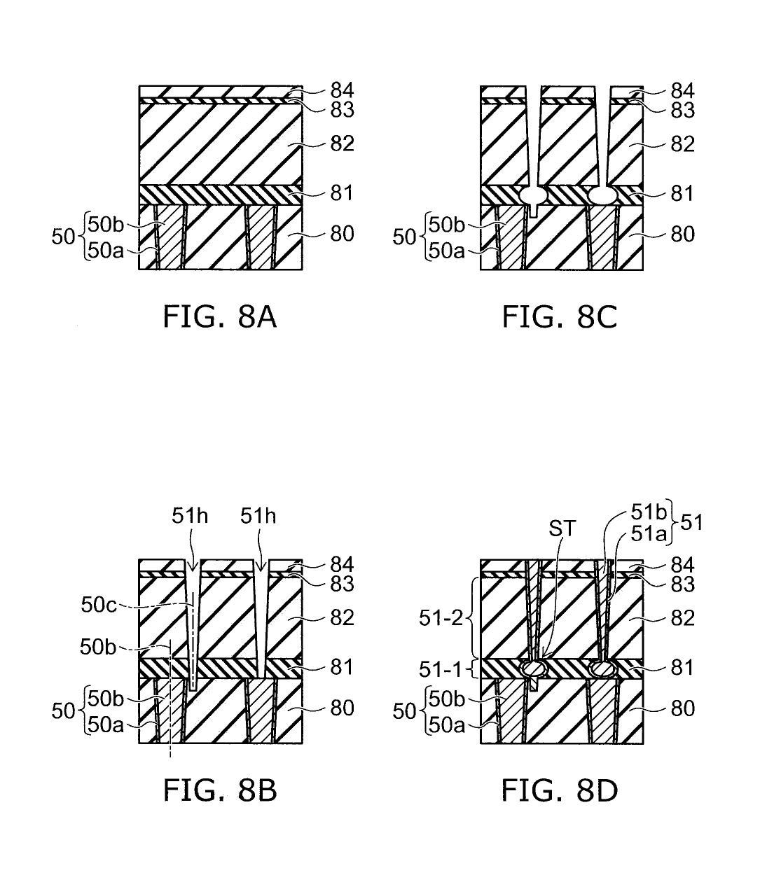

FIGS. 8A to 8D are schematic sectional views showing a process for manufacturing the contact electrode of a nonvolatile semiconductor memory device according to the second embodiment.

First, as shown in FIG. 8A, the state with a contact electrode 50 formed in an insulating layer 80 is prepared. That is, in this stage, a contact electrode 50 for electrically connecting the contact electrode 51 with the select transistor is previously formed below the contact electrode 51 already shown in FIG. 2A. Then, an insulating layer 81 (second insulating layer) different in component from the insulating layer 80 is formed on the insulating layer 80 and on the contact electrode 50. Furthermore, an insulating layer 82 different in component from the insulating layer 81 is formed on the insulating layer 81. That is, the insulating layer 81 is formed before forming the insulating layer 82 above the semiconductor layer 10. For instance, the insulating layer 80, 82 includes a silicon oxide layer. The insulating layer 81 includes a silicon nitride layer.

Next, as shown in FIG. 8B, a contact hole 51h piercing the insulating layer 84, the insulating layer 83, and the insulating layer 81 is formed from the surface of the insulating layer 84 by photolithography and anisotropic etching (e.g., RIE). Here, as shown, the center line 51c of the contact hole 51h and the center line 50c of the contact electrode 50 may be displaced from each other.

Next, as shown in FIG. 8C, the insulating layer 81 exposed in the contact hole 51h is selectively etched by isotropic etching (e.g., wet etching). For instance, the inside of the contact hole 51h is exposed to a solution capable of etching the insulating layer 81 faster than the insulating layer 80, 82 to selectively etch the insulating layer 81 exposed in the contact hole 51h.

Thus, the inner wall of the contact hole 51h at the position of the insulating layer 81 has a curved surface. That is, after the selective etching, the width (width in the X-direction and the Y-direction) of the contact hole 51h at the position of the insulating layer 81 is selectively expanded.

Furthermore, the formation of such a contact hole 51h reliably exposes the upper end of the contact electrode 50 at the bottom of the contact hole 51h.

Next, as shown in FIG. 8D, a barrier layer 51a and a conductive layer 51b are sequentially formed in the contact hole 51h. Thus, a contact electrode 51 is formed in the contact hole 51h. The lower end of the contact electrode 51 is in contact with the contact electrode 50. The upper end of the contact electrode 51 is in contact with the interconnection layer 52 (not shown in FIG. 8D, see FIG. 2A).

As shown in FIG. 8D, the contact electrode 51 in the second embodiment includes a first part 51-1 being in contact with the contact electrode 50, and a second part 51-2 being in contact with the interconnection layer 52 and forming a step difference with respect to the first part 51-1. In the cross section (X-Y cross section) cutting the contact electrode 51 across the extending direction (Z-direction) of the contact electrode 51, the first part 51-1 below the step difference ST indicated by arrow ST has a width wider than the width of the second part 51-2 at the position of the step difference ST. The first part 51-1 is in contact with the insulating layer 81.

Thus, according to the second embodiment, even if there is a misalignment between the contact hole 51h and the contact electrode 50, the contact electrode 51 formed in the contact hole 51h can be reliably made continuous with the contact electrode 50 by selectively expanding the width of the lower part of the contact hole 51h.

In the embodiments described above, “above” expressed in “A portion A is provided above a portion B” may be used as the case where the portion A does not contact the portion B and the portion A is provided upward the portion B other than the case where the portion A contacts the portion B and the portion is provided on the portion B. “The portion A is provided above the portion B” may be applied to the case where the portion A and the portion B are reversed and the portion A is placed below the portion B or the case where the portion A is placed beside the portion B. This is because the structure of the semiconductor device does not change before and after the rotation even if the semiconductor device according to the embodiment is rotated.

Although the embodiments are described above with reference to the specific examples, the embodiments are not limited to these specific examples. That is, design modification appropriately made by a person skilled in the art in regard to the embodiments is within the scope of the embodiments to the extent that the features of the embodiments are included. Components and the disposition, the material, the condition, the shape, and the size or the like included in the specific examples are not limited to illustrations and can be changed appropriately.

The components included in the embodiments can be combined to the extent of technical feasibility and the combinations are included in the scope of the embodiments to the extent that the feature of the embodiments is included. Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor layer including a first region and a second region placed outside the first region;
a first insulating layer provided above the semiconductor layer;
a first contact electrode extending in a first direction from the semiconductor layer toward the first insulating layer, having a sidewall surrounded with the first insulating layer, and electrically connected to a first element provided in the first region;
a second contact electrode extending in the first direction, having a sidewall surrounded with the first insulating layer, and electrically connected to a second element provided in the second region;
a first interconnection layer connected to an upper end of the first contact electrode, extending in a second direction crossing the first direction, and having a sidewall surrounded with the first insulating layer; and
a second interconnection layer connected to an upper end of the second contact electrode, extending in the second direction crossing the extending direction of the second contact electrode, having a sidewall surrounded with the first insulating layer, and having a line width wider than a line width of the first interconnection layer.

2. The device according to claim 1, wherein a distance from a lower surface of the semiconductor layer to an upper end of the first interconnection layer is equal to a distance from the lower surface of the semiconductor layer to an upper end of the second interconnection layer.

3. The device according to claim 1, further comprising:
a third contact electrode electrically connecting the first contact electrode with the first element,
the first contact electrode including a first part being in contact with the third contact electrode, and a second part being in contact with the first interconnection layer and having a step difference with respect to the first part, and
in a cross section cutting the first contact electrode across the first direction, the first part below position of the step difference having a width wider than a width of the second part at the position of the step difference.

4. The device according to claim 3, further comprising:
a second insulating layer below the first insulating layer,
the first part being in contact with the second insulating layer.

5. The device according to claim 1, wherein the first region is a memory cell region, and the second region is a peripheral circuit region.

6. The device according to claim 1, wherein the first element is a select gate transistor configured to select one of a plurality of memory strings.

7. A method for manufacturing a semiconductor device, comprising:
preparing a semiconductor layer including a first element in a first region and including a second element in a second region outside the first region;
forming a first insulating layer above the semiconductor layer;
forming a third insulating layer different in composition from the first insulating layer on the first insulating layer;
forming a fourth insulating layer different in composition from the third insulating layer on the third insulating layer;
forming a first contact electrode extending in a first direction from the fourth insulating layer toward the semiconductor layer, having a sidewall surrounded with the first insulating layer, the third insulating layer, and the fourth insulating layer, and electrically connected to the first element, and a second contact electrode extending in the first direction, having a sidewall surrounded with the first insulating layer, the third insulating layer, and the fourth insulating layer, and electrically connected to the second element;
removing the fourth insulating layer, the first contact electrode above the third insulating layer, and the second contact electrode above the third insulating layer;
forming a mask layer on the third insulating layer, the mask layer opening the first contact electrode and opening the second contact electrode and a part of the third insulating layer in contact with the second contact electrode;
forming a first trench with a bottom being an upper end of the first contact electrode located below the third insulating layer by etching the first contact electrode opened through the mask layer, and forming a second trench with a bottom being an upper end of the second contact electrode and the first insulating layer continuous with the upper end of the second contact electrode by etching the second contact electrode and the part of the third insulating layer in contact with the second contact electrode opened through the mask layer;
forming a conductive layer above the third insulating layer, in the first trench, and in the second trench; and
forming a first interconnection layer connected to the upper end of the first contact electrode and a second interconnection layer connected to the upper end of the second contact electrode by removing the third insulating layer and the conductive layer above a junction of the first insulating layer and the third insulating layer.

8. The method according to claim 7, wherein in the forming the first trench, the first trench is formed so as to extend in a second direction crossing the first direction.

9. The method according to claim 7, wherein in the forming the first trench, the second trench is formed so as to extend in a second direction crossing the first direction.

10. The method according to claim 7, wherein
before the forming the first insulating layer, a second insulating layer different in component from the first insulating layer is formed above the semiconductor layer, and
in the forming the first contact electrode, after forming a contact hole piercing the fourth insulating layer, the third insulating layer, and the second insulating layer from a surface of the fourth insulating layer by anisotropic etching, and then selectively etching the second insulating layer exposed in the contact hole by isotropic etching, the first contact electrode is formed in the contact hole.

11. The method according to claim 10, wherein
before the forming the third insulating layer, a third contact electrode electrically connecting the first contact electrode with the first element is formed below the first contact electrode, and
in the forming the first contact electrode, an upper end of the third contact electrode is exposed at a bottom of the contact hole by forming the contact hole.
